(19) United States
(12) Patent Application Publication
(10) Pub. No.: US 2024/0186460 A1
(43) Pub. Date: Jun. 6, 2024

(54) METHOD FOR PRODUCING A COMPONENT HAVING A CAVITY, AND COMPONENT HAVING A CAVITY

(71) Applicant: ams-OSRAM International GmbH, Regensburg (DE)

(72) Inventor: Lutz HÖPPEL, Alteglofsheim (DE)

(21) Appl. No.: 18/287,727

(22) PCT Filed: Apr. 5, 2022
(86) PCT No.: PCT/EP2022/058954

§ 371 Date: Oct. 20, 2023

(30) Foreign Application Priority Data
Apr. 21, 2021 (DE) 10 2021 110 089.5

(51) Int. Cl. H01L 33/48; H01L 25/16; H01L 33/60; H01L 33/62

(52) U.S. Cl. CPC H01L 33/486; H01L 25/167; H01L 33/60; H01L 33/62; H01L 2933/0066

(57) ABSTRACT

A component includes a carrier, at least one semiconductor chip, an intermediate layer and a cover layer. The semiconductor chip, the intermediate layer and the cover layer are arranged on the carrier. The cover layer has at least one cavity wherein the semiconductor chip is arranged. The intermediate layer is electrically insulating and is arranged in regions along the vertical direction between the carrier and the cover layer. The intermediate layer extends along lateral direction into the cavity and adjoins the semiconductor chip. The cover layer has a vertical height that varies depending on the lateral positions of the cover layer and has a reduced vertical height at the positions of the intermediate layer.

A component having at least one cavity is disclosed. Furthermore, a method for producing a component, in particular the component having at least one cavity or several cavities, is disclosed.

In an optoelectronic component, for example in the form of a display, a suitable reflective environment should be created around each emission point, such as around each pixel suitable for beam shaping. Such a component usually has cavities, wherein individual light-emitting semiconductor chips, such as light-emitting semiconductor diodes or micro-LEDs, are arranged. If the cavities have vertical depths that are smaller or barely larger than the usual vertical heights of the semiconductor chips, the cavities could be formed before the semiconductor chips are attached. Side walls of the cavities can be provided with thin radiation-reflecting metal layers. Such metal layers can at the same time be configured for electrically contacting the semiconductor chips arranged in the cavities. However, this involves a latent risk of possible short circuits during the electrical wiring of the semiconductor chips as well as during operation of the component.

It was found that the deeper the cavities, the better a desired forward emission can be achieved. Therefore, cavities whose depths are significantly greater than the vertical heights of the semiconductor chips placed in the cavities are desirable. However, deeper cavities hinder the placement as well as the wiring of the semiconductor chips, since larger topographical differences would have to be overcome.

One object is to specify a component, in particular an optoelectronic component in the form of a display, with high compactness, improved beam shaping properties and increased stability against electrical short circuits. Another object is to disclose a reliable and cost-efficient method for producing a component, in particular a component described herein.

These objects are solved by the component according to the independent claim and by the method for producing a component according to a further independent claim. Further designs and further developments of the component or the method are subject matter of the dependent claims.

According to at least one embodiment of a component, it comprises a carrier, at least one semiconductor chip and a cover layer. The cover layer is arranged on the carrier, for example, and has a cavity, in which the semiconductor chip is arranged. In particular, the semiconductor chip is configured to generate electromagnetic radiation in the infrared, visible or ultraviolet spectral range. The semiconductor chip may be a micro-LED. The cover layer has a vertical height that varies depending on the lateral positions of the cover layer, for example. The cover layer may have a reduced vertical height at positions of the intermediate layer.

For clarity reasons, a component is described below often only in the context of at least one semiconductor chip and at least one cavity in the cover layer. However, it is possible for such a component to have a single semiconductor chip and a single cavity in the cover layer, or a plurality of cavities in the cover layer and a plurality of semiconductor chips. The features of the component described below in connection with a semiconductor chip and a cavity can be used analogously for a component having a plurality of semiconductor chips and a plurality of cavities in the cover layer. For example, exactly one of the semiconductor chips or a plurality of semiconductor chips is/are disposed in each of the cavities. The component may be an optoelectronic component, in particular a display. Each cavity with the semiconductor chip/s arranged therein may form an image point, i.e. a pixel, of the component.

According to at least one embodiment of the component, it has an intermediate layer. The intermediate layer is, for example, electrically insulating. Along the vertical direction, the intermediate layer can be arranged in regions between the carrier and the cover layer. It is possible that the intermediate layer and/or the cover layer are/is arranged directly on the carrier in places. Along lateral direction, the intermediate layer may extend into the cavity or cavities. For example, the intermediate layer adjoins the semiconductor chip arranged in the cavity, in particular directly.

In top view, the intermediate layer inside the cavity or cavities can be free from being covered by the cover layer. Outside the cavity or cavities, the intermediate layer can be covered, in particular completely covered, by the cover layer. If the cover layer has a plurality of cavities, the intermediate layer may have a plurality of sublayers, in particular a plurality of laterally spaced sublayers, wherein the sublayers each extend into or throughout one of the cavities. A lateral direction is understood to be a direction that is directed in particular parallel to a main extension surface of the carrier. A vertical direction is understood to be a direction that is directed in particular perpendicular to the main extension surface of the carrier. The vertical direction and the lateral direction are orthogonal to each other.

In at least one embodiment of a component, it comprises a carrier, at least one semiconductor chip, an intermediate layer and a cover layer. The semiconductor chip, the intermediate layer and the cover layer are arranged on the carrier. The cover layer has at least one cavity, in which the semiconductor chip is arranged. The intermediate layer is arranged along a vertical direction in regions between the carrier and the cover layer. The intermediate layer extends along a lateral direction into the cavity, wherein the intermediate layer adjoins the semiconductor chip, in particular directly adjoins the semiconductor chip arranged in the cavity.

With the use of the intermediate layer, which is formed to be electrically insulating, for example, the risk of short circuits between electrical leads or connections to the semiconductor chip can be largely avoided or eliminated. During the production of the component, the chip transfer can take place on flat surfaces and therefore does not require complex stepped stamps, which would have a negative effect on placement accuracy. Permanent bonding of semiconductor chips to designated mounting surfaces is reproducible and can be made much more reliable. Wiring starting from a front side of the semiconductor chip should overcome only a minimum of topography. Furthermore, significantly deeper cavities could be formed. This allows more possibilities for beam shaping and, in particular, allows for stronger forward emission.

In addition, inner walls or side flanks of the cavity can be provided with a reflective material in a simple manner, wherein the reflective material can be selected independently of a material of electrical contact layers. This degree of freedom allows in particular the elimination of possible cover layers, which are otherwise recommended, for example, for a more reliable generation of the chip interconnect or for the necessary insulation. Without such cover layers, significantly higher degrees of reflectivity can be achieved for the side flanks of the cavity.

According to at least one embodiment of the component, the intermediate layer fully encloses the semiconductor chip in lateral directions. The intermediate layer may partially or completely cover side surfaces of the semiconductor chip. In particular, a front side or a rear side of the semiconductor chip is free from being covered by the intermediate layer, in particular except for hollow spaces under the semiconductor chip starting from its side flanks. These hollow spaces may be partially or completely filled with the intermediate layer.

According to at least one embodiment of the component, the intermediate layer has a lateral width that is greater than a lateral width of the semiconductor chip. The intermediate layer may fully or only partially surround the semiconductor chip in lateral directions. For example, the intermediate layer completely covers at least one side surface of the semiconductor chip along its entire width. Other side surfaces of the semiconductor chip may be covered by the intermediate layer only in certain regions or not at all.

According to at least one embodiment of the component, the intermediate layer has a lateral width that is smaller than a lateral width of the semiconductor chip. For example, the intermediate layer only partially covers a side surface of the semiconductor chip. In particular, the intermediate layer only partially covers the side surface of the semiconductor chip along the entire width of the side surface.

According to at least one embodiment of the component, the semiconductor chip has a front side facing away from the carrier, which is flush with the intermediate layer in the vertical direction or projects vertically beyond the intermediate layer. Deviating from this, it is also possible that a front side of the intermediate layer slightly overhangs the front side of the semiconductor chip along the vertical direction.

According to at least one embodiment of the component, it has a reflective layer formed on inner walls of the cavity. The reflective layer may be formed of an electrically insulating material. Alternatively, it is possible that the reflective layer is formed of an electrically conductive material. For example, the reflective layer is electrically insulated from the semiconductor chip.

According to at least one embodiment of the component, it has a first contact layer and a second contact layer for electrical contacting of the semiconductor chip. The intermediate layer is arranged in regions along the vertical direction between the first contact layer and the second contact layer, wherein the intermediate layer electrically insulates the first contact layer from the second contact layer. The first contact layer or the second contact layer may be formed from a radiation-transmitting electrically conductive material. In particular, the semiconductor chip is located between the first contact layer and the second contact layer. In particular, the semiconductor chip has a first electrical contact layer on its rear side and a second electrical contact layer on its front side. For example, the first contact layer is electrically isolated from the second contact layer by the intermediate layer.

According to at least one embodiment of the component, the semiconductor chip partially covers the first contact layer in top view. The first contact layer has at least one subregion or subregions, wherein the subregion or subregions protrudes or protrude laterally from the semiconductor chip in top view. The protruding subregion or subregions of the first contact layer may be at least partially or completely covered by the intermediate layer in top view.

According to at least one embodiment of the component, the semiconductor chip is arranged in the vertical direction between the first contact layer and the second contact layer. The second contact layer may be arranged on a front side of the semiconductor chip facing away from the carrier. For example, the second contact layer covers the front side of the semiconductor chip at least partially or completely. For example, the second contact layer is formed from a radiation-transmitting material, in particular from a transparent and electrically conductive material.

According to at least one embodiment of the component, the carrier has a base body, in particular an electrically insulating base body, through-contacts, inner connection layers and outer connection layers. In particular, the inner connection layers and the outer connection layers are arranged on opposite surfaces of the base body. For example, the through-contacts extend throughout the base body. The through-contacts can each electrically connect one of the inner connection layers to one of the outer connection layers.

According to at least one embodiment of the component, the semiconductor chip has a vertical height. The cavity has a vertical depth. A ratio of the vertical depth of the cavity to the vertical height of the semiconductor chip may be from 2 to 20, for example from 2 to 15, from 2 to 10, from 2 to 5 inclusive, from 3 to 10, or from 5 to 10.

According to at least one embodiment of the component, it has a plurality of semiconductor chips. The cover layer may have a plurality of cavities, wherein at least one or exactly one of the semiconductor chips is arranged in each of the cavities, whose inner walls are provided in particular with a reflective layer.

A method for producing a component, in particular of a component described herein, is disclosed, wherein the cavity or the plurality of cavities is/are formed only after the semiconductor chip or chips have been placed or arranged or after the semiconductor chips have been electrically wired. Since the cavities are formed, in particular as openings of the cover layer, only after the positioning and/or electrical contacting of the semiconductor chips, the arrangement or wiring of the semiconductor chips can be carried out without significant differences in the topography on the carrier, which is formed, for example, as a display backplane.

After placing or arranging the semiconductor chip or semiconductor chips on the carrier, the intermediate layer can be formed on the carrier for topography compensation. For example, the intermediate layer and the semiconductor chips differ in their vertical heights by at most 30%, 25%, 20%, 10%, 5%, or at most 3%. It is possible that the intermediate layer is flush with the associated semiconductor chip at a vertical plane. Planar contacting of the semiconductor chip, at least in places, can thus be achieved due to the small or hardly existing differences in the topography. The intermediate layer can be formed to be electrically insulating. In this case, the intermediate layer can electrically insulate different contact layers, which are arranged above and below the intermediate layer, for example, from one another.

The intermediate layer can also be formed to be radiation-transmissive. For example, the material composition and layer thickness of the intermediate layer are such that it has a transmittance of at least 50%, 60%, 70%, 80% or at least 90% for radiation in the visible or ultraviolet spectral range. An intermediate layer formed in this way has hardly any negative influence on the efficiency of the component.

The method described here is particularly suitable for the production of a component described here. The features described in connection with the component can therefore also be used for the method, and vice versa.

In at least one embodiment of a method for producing a component having a carrier, at least one semiconductor chip, an intermediate layer and a cover layer, the semiconductor chip is arranged on the carrier. The intermediate layer is disposed on the carrier, wherein the intermediate layer is laterally adjacent to the semiconductor chip. The cover layer is applied to the intermediate layer and to the carrier, wherein at least one cavity, in which the semiconductor chip is arranged, is formed in the cover layer. The intermediate layer is disposed along the vertical direction in a region-wise manner between the carrier and the cover layer. The intermediate layer extends into the cavity along the lateral direction. In particular, arranging the semiconductor chip, applying the intermediate layer, and applying the cover layer are performed in the specified order.

According to at least one embodiment of the method, the semiconductor chip is electrically wired before the cover layer is applied to the intermediate layer and to the carrier. The semiconductor chip can thus be positioned and wired in a simple manner. Since the cavity is formed after the semiconductor chip is positioned, the cavity with any vertical depth can be formed in a simple manner.

According to at least one embodiment of the method, a planar contact layer is formed on a front side of the intermediate layer facing away from the carrier for electrical wiring of the semiconductor chip.

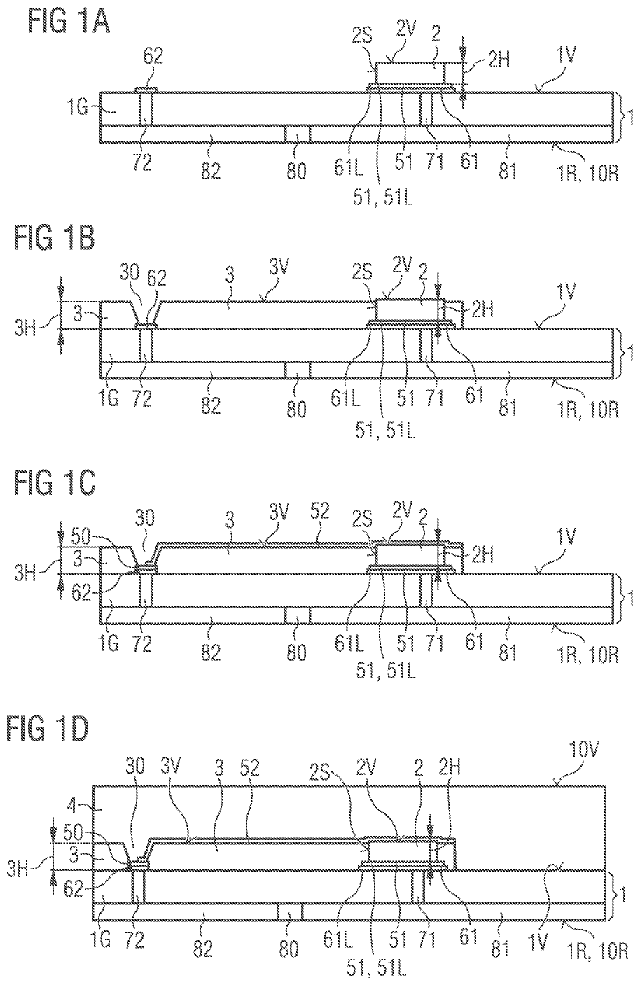

Further embodiments and further developments of the component or of the method for producing the component are apparent from the embodiment examples explained below in connection with FIGS. 1A to 5.

FIGS. 1A, 1B, 1C, 1D, 1E and 1F show schematic representations of various method steps of an embodiment of a process for producing a component, which is shown schematically in particular in FIG. 1F in sectional view and in FIG. 1G in top view.

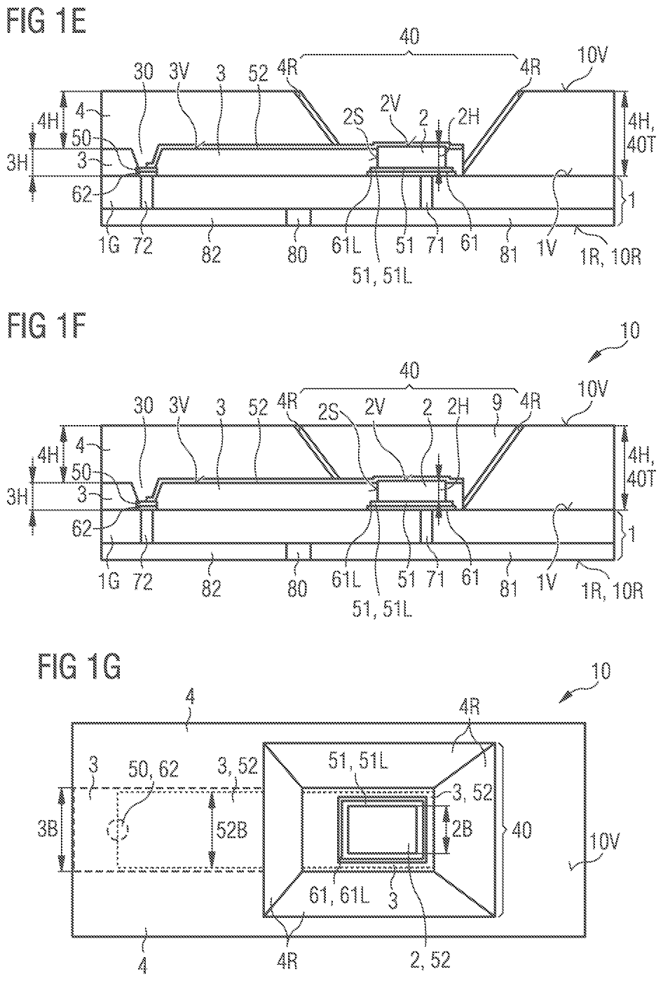

FIGS. 2A and 2B show schematic representations of a further embodiment of a component in sectional view and in top view.

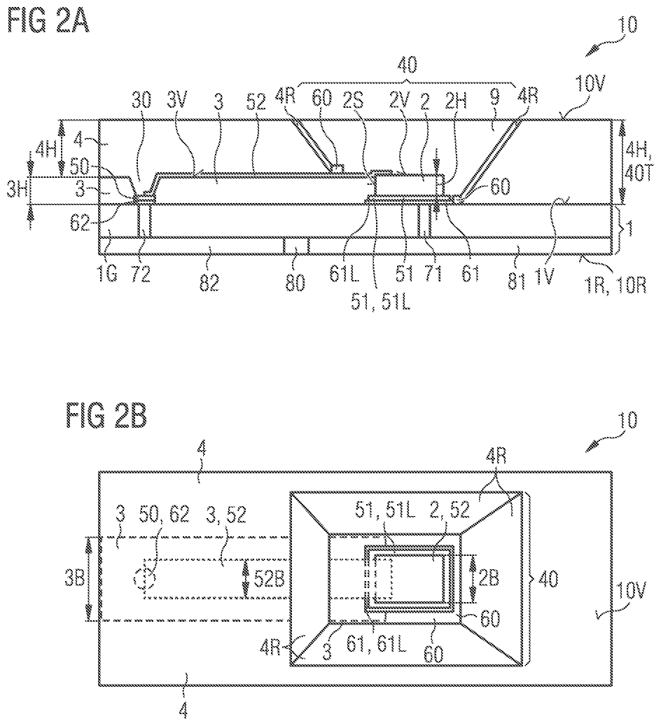

FIG. 3A shows schematic representation of a method step according to a further embodiment of a method for producing a component, which is schematically represented in particular in FIG. 3B in sectional view and in FIG. 3C in top view.

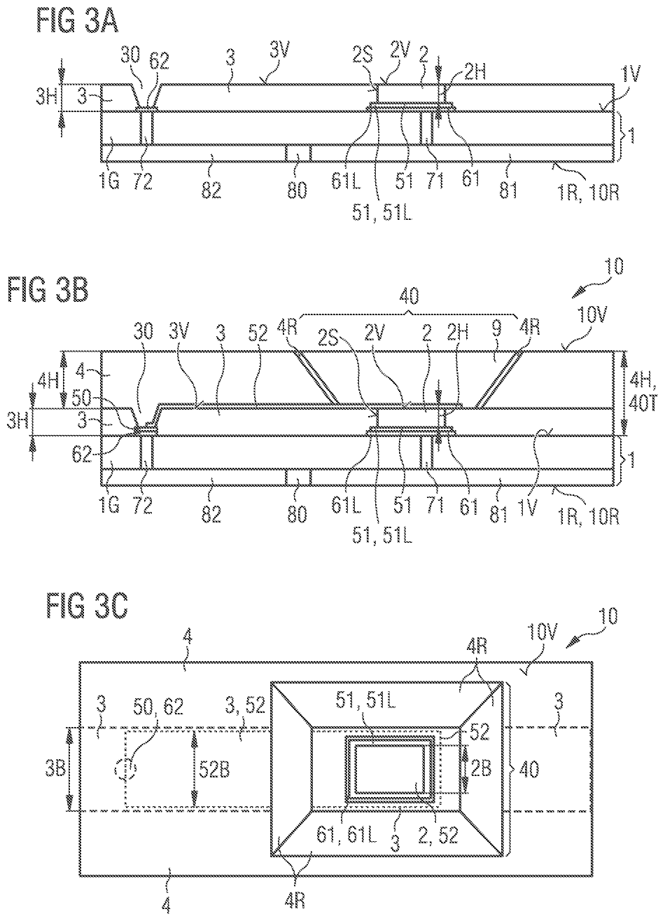

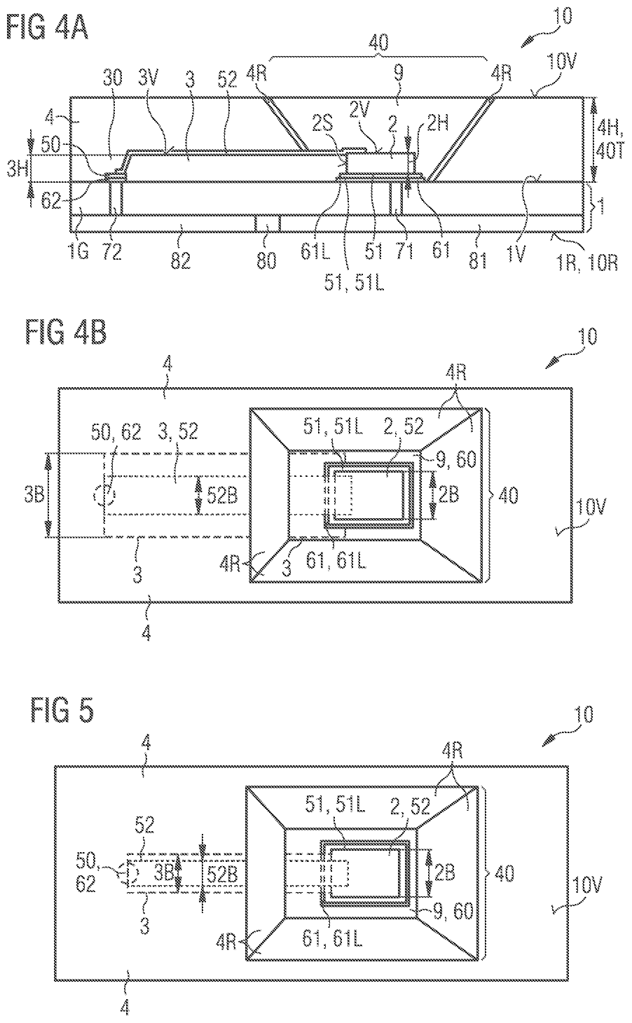

FIGS. 4A, 4B and 5 show schematic representations of further embodiments of a component in sectional view or in top view.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

FIGS. 1A to 1F show different method steps of a method for producing a component 10. According to FIG. 1A, a carrier 1 is provided on which at least one semiconductor chip 2 or a plurality of semiconductor chips 2 is or are positioned or mounted. The carrier 1 may be a carrier plate or part of the carrier plate of a display. The carrier 1 or the carrier plate may have a plurality of transistors, such as a plurality of thin-film transistors (TFT), which are not shown in FIG. 1A for clarity. The transistors are configured for driving, in particular for individually driving the semiconductor chips 2. The carrier 1 can be a so-called TFT backplane. It is also possible that the transistors are integrated in a separate control board.

According to FIG. 1A, the carrier 1 has a base body 1G that mechanically stabilizes the carrier 1. The base body 1G may account for at least 50%, 60%, 80% or 90% of the total volume or weight of the carrier 1. For example, the base body 1G is formed of an electrically insulating material. The carrier 1 has a front side 1V which may be formed in regions by surface of the base body 1G.

The carrier 1 has at least a first inner connection layer 61 and a second inner connection layer 62 on a front side of the base body 1G, which are spatially spaced apart from each other in the lateral direction and, in particular, are assigned to different electrical polarities of the component 1. The carrier 1 may have a plurality of such pairs of the first inner connection layer 61 and the second inner connection layer 62, wherein the pairs each are assigned to a semiconductor chip 2, for example. Each pair of the first inner connection layer 61 and the second inner connection layer 62 may be arranged for electrically contacting a semiconductor chip 2, in particular exactly one semiconductor chip 2. It is also possible for the component 1 to have a common internal electrode instead of the first internal connection layers 61 or instead of the second internal connection layers 62. For example, the component 1 has a common electrode and a plurality of second inner connection layers 62 or a plurality of first inner connection layers 61. The second inner connection layers 62 or the first inner connection layers 61 may be arranged in openings of the common, in particular contiguous, electrode.

The carrier 1 has at least a first outer connection layer 81 and a second outer connection layer 82 on a rear side of the base body 1G, which are spatially spaced apart from one another in the lateral direction and, in particular, are spatially spaced apart from one another and are electrically insulated by an electrically insulating separating layer 80. A rear side 10R of the component 10 or a rear side 1R of the carrier 1 may be formed in regions by surfaces of the outer connection layers 81 and 82 and in regions by surfaces of the separating layer 80. The carrier 1 may have a plurality of such pairs of the first outer connection layer 81 and the second outer connection layer 82. It is possible for the carrier 1 to have a common outer electrode instead of the first outer connection layers 81 or instead of the second outer connection layers 82. The second outer connection layers 82 or the first outer connection layers 81 can be arranged in openings of the common outer, in particular contiguous, electrode.

In particular, the semiconductor chip 2 is externally electrically connectable via the rear side 1R or 10R, for example exclusively via the rear side 1R or 10R, at the outer connection layers 81 and 82. The component 1 may be part of a larger composite such that, in particular, the rear side 1R or 10R is not exposed. For example, the composite has a carrier plate on which the component 1 is arranged. The carrier plate may have transistors which are configured to electrically control, in particular for individually electrically control the semiconductor chips 2.

The carrier 1 has at least a first through-contact 71 and a second through-contact 72. The through-contacts 71 and 72 extend along the vertical direction, in particular throughout the base body 1G. Via the first/second through-contact 71/72, the first/second outer connection layer 81/82 is electrically conductively connected to the first/second inner connection layer 61/62. The carrier 1 may have a plurality of such pairs of first through-contact 71 and second through-contact 72. For example, the first connection layers 61 and 81 and the first through-contact 71 are assigned to a first electrode, such as to an anode of the component 10. The second connection layers 62 and 82 and the second through-contact 72 may be assigned to a second electrode, such as to a cathode of the component 10 or the semiconductor chip 2. A transistor may be connected to the anode or to the cathode for driving the semiconductor chip 2.

According to FIG. 1A, the semiconductor chip 2 is electrically connected to the first inner connection layer 61 via a first contact layer 51. The first contact layer 51 is located along the vertical direction between the semiconductor chip 2 and the first inner connection layer 61. In a top view of the front side 1V of the base body 1G or the carrier 1, the first contact layer 51 or the first inner connection layer 61 may protrude laterally beyond one side surface 2S or beyond a plurality of side surfaces 2S of the semiconductor chip 2. This lateral edge region is schematically shown in FIG. 1A as a lateral subregion 51L of the first contact layer 51 or as a lateral subregion 61L of the first inner connection layer 61. In a top view of the front side 1V of the carrier 1, the lateral subregion 51L or 61L is free from being covered by the semiconductor chip 2.

The semiconductor chip 2 has a front side 2V. In particular, the front side 2V is a radiation exit face of the semiconductor chip 2. The semiconductor chip 2 may be formed as a volume emitter. In this case, the side surfaces 2S may also be radiation exit surfaces. Also, part or all of the rear side of the semiconductor chip 2 may be formed as a radiation exit surface. For example, the first contact layer 51 is formed of a transparent electrically conductive material, such as indium tin oxide (ITO). The underlying first inner connection layer 61 may be formed as an electrically conductive mirror layer. For example, the first inner connection layer 61 comprises CrMo/MoAl. Notwithstanding the above, it is possible that the first contact layer 51 is formed of an electrically conductive and radiation reflective material.

According to FIG. 1B, an intermediate layer 3 is applied to the carrier 1, in particular after the semiconductor chip 2 has been arranged. The intermediate layer 3 adjoins the semiconductor chip 2, in particular directly adjoins the semiconductor chip 2. In a top view of the front side 1V of the carrier 1, the intermediate layer 3 may partially or completely surround the semiconductor chip 2. A side surface 2S or a plurality of side surfaces 2S of the semiconductor chip 2 may be partially or completely covered by a material of the intermediate layer 3. In particular, the material of the intermediate layer 3 is a radiation-transmissive material.

The semiconductor chip 2 has a vertical height 2H. The intermediate layer 3 has a vertical height 3H. It is possible that the vertical height 2H differs from the vertical height 3H by at most 30%, 20%, 15%, 10%, 5%, or at most 3%. Along the vertical direction, the semiconductor chip 2 may slightly protrude beyond the intermediate layer 3, or vice versa. However, it is possible that within the manufacturing tolerances, the front side 2V of the semiconductor chip 2 is flush with a front side 3V of the intermediate layer 3 facing away from the carrier 1. The manufacturing tolerances may be in the micrometer range, such as ±1 μm or less, for example ±800 nm, ±500 nm, ±300 nm or ±100 nm.

The intermediate layer 3 can initially be applied extensively to the carrier 1, in particular to the base body 1G, to the second inner connection layer 62 and to the semiconductor chip 2. In a subsequent method step, subregions of the carrier 1, such as subregions of the base body 1G and the second inner connection layer 62, as well as of the front side 2V of the semiconductor chip 2 can be exposed from the material of the intermediate layer 3. For example, intermediate layer 3 is patterned using a mask. As schematically shown in FIG. 1B, the intermediate layer 3 has at least one opening 30, wherein the second inner connection layer 62 is freely accessible in regions.

If the component 10 has a plurality of semiconductor chips 2, the intermediate layer 3 can be adjacent to each of the semiconductor chips 2, in particular directly adjacent to each of the semiconductor chips 2. The intermediate layer 3 may be contiguous. Alternatively, it is possible for the intermediate layer 3 to have a plurality of laterally spaced sublayers, wherein the sublayers each are adjacent to a semiconductor chip 2, in particular to exactly one of the semiconductor chips 2.

Referring to FIG. 1C, a second contact layer 52 is formed on the intermediate layer 3. In particular, the second contact layer 52 extends from the opening 30 of the intermediate layer 3 over the front side 3V of the intermediate layer 3 to the front side 2V of the semiconductor chip 2. In particular, the second contact layer 52 is formed from an electrically conductive transparent material, such as from an electrically conductive transparent oxide (TCO). The second contact layer 52 may partially or completely cover the front side 2V of the semiconductor chip 2.

Outside the opening 30, the second contact layer 52 may be a planar contact. Within the opening 30, the second contact layer 52 extends along the vertical direction from a bottom surface of the opening 30 via side walls of the opening 30 to the front side 3V of the intermediate layer 3. Within the opening 30, an intermediate connection layer 50 may be formed to achieve improved electrical contact and is disposed between the second contact layer 52 and the second inner connection layer 62.

The semiconductor chip 2 is electrically conductively connected to the outer connection layers 81 and 82 via the first contact layer 51 and the second contact layer 52. The intermediate layer 3 is located along the vertical direction in regions between the first contact layer 51 and the second contact layer 52. The intermediate layer 3 thus serves in particular as an insulating layer between the first contact layer 51 and the second contact layer 52. Lateral subregions 51L or 61L of the first contact layer 51 or of the first inner connection layer 61, which protrude laterally from the semiconductor chip 2 in a plan view of the front side 1V of the carrier 1, can be partially or completely covered by the intermediate layer 3. Possible short-circuit risks are thus significantly reduced.

According to FIG. 1D, the cover layer 4 is formed. The cover layer 4 can be formed from a lacquer material, in particular from a lacquer with photoactive ingredients. In particular, a material of the cover layer 4 is applied to exposed surfaces of the intermediate layer 3, the second contact layer 52, the carrier 1, in particular the base body 1G, and/or of the semiconductor chip 2. The opening 30 of the intermediate layer 3 may be completely filled with the material of the cover layer 4. The cover layer 4 may be indirectly or directly adjacent to the intermediate layer 3, to the second contact layer 52, to the carrier 1, to the base body 1G of the carrier 1, and/or to the semiconductor chip 2. It is possible that in a top view of the carrier 1, the cover layer 4 initially completely covers the intermediate layer 3, the second contact layer 52, the semiconductor chip 2 and/or the carrier 1.

According to FIG. 1E, a cavity 40 is formed in the cover layer 4. The cavity 40 can be formed by patterning the cover layer 4, for example by removing the material of the cover layer 4, at the position of the semiconductor chip 2. It is possible that the cover layer 4 is patterned downstream using its photoactive ingredient/s. It is possible that subregions of the second contact layer 52, the intermediate layer 3, the semiconductor chip 2 and/or the carrier 1 are exposed in the cavity 40. In particular, only a portion of the component 10 having a cavity 40 in the cover layer 4 is schematically shown in FIG. 1E. Deviating therefrom, it is possible that the component 10 has several such sections, in particular contiguous sections, with a plurality of corresponding cavities 40.

As schematically shown in FIG. 1E, the cover layer 4 has a vertical height 4H. Depending on the lateral positions of the cover layer 4, the vertical height 4H can be different. For example, if the cover layer 4 is directly adjacent to the carrier 1 at a first position, the cover layer 4 may have a maximum vertical height 4H that defines a vertical depth 40T of the cavity 40, in particular the maximum vertical depth 40T of the cavity 40. If the cover layer 4 is directly adjacent to the second contact layer 52 or to the intermediate layer 3 at a second position, for example, the cover layer 4 has a reduced vertical height 4H compared to the first position. The maximum vertical depth 40T of the cavity 40, which is given by the maximum vertical height 4H of the cover layer 4, is in particular greater than or equal to the sum of the vertical height 3H of the intermediate layer 3, the layer thickness of the second contact layer 52 and the reduced vertical height 4H.

A ratio of the vertical depth 40T of the cavity 40 to the vertical height 2H of the semiconductor chip 2 may be from 2 to 20, for example from 2 to 15, from 2 to 10, from 2 to 5, from 3 to 10, or from 5 to 10.

According to FIG. 1E, the inner walls of the cavity 40 are provided with a reflective layer 4R. In particular, the inner walls of the cavity 40 are/is completely covered with a material of the reflective layer 4R. In particular, the inner walls of the cavity 40 are sloped. As the vertical distance from the carrier 1 increases, the cavity 40 may have an increasing cross-section. The reflective layer 4R may be formed from an electrically insulating material or from an electrically conductive material. If the reflective layer 4R is formed to be electrically conductive, it is possible for the reflective layer 4R to be in electrical contact with the second contact layer 52. However, it is preferred that the reflective layer 4R is electrically isolated from the second contact layer 52. For example, as schematically shown in FIGS. 2A and 2B, an insulating layer 60 is located between the reflective layer 4R and the second contact layer 52.

According to FIG. 1F, the cavity 40 can be partially or completely filled with an encapsulation layer 9. In particular, the encapsulation layer 9 is formed to be radiation-transmissive. It is possible that the encapsulation layer 9 comprises scattering particles, reflection particles and/or luminescent materials for converting the radiation emitted by the semiconductor chip 2. It is also possible that at least one converter plate is arranged in the cavity 40 or on the cavity 40.

FIG. 1G shows the component 10 shown in particular in FIG. 1F in top view. The intermediate layer 3 has the form of a connecting web on which the second contact layer 52 is formed. The intermediate layer 3 has a lateral width 3B, which is in particular greater than a lateral width 52B of the second contact layer 52. As shown schematically in FIG. 1G, the intermediate layer 3 extends along the lateral direction into the cavity 40. In top view, the intermediate layer 3 is thus located both inside and outside the cavity 40. The semiconductor chip 2 arranged in the cavity 40 is completely surrounded by the intermediate layer 3 in the lateral direction. The lateral subregions 51L and 61L of the first contact layer 51 and the first inner connection layer 61, respectively, which protrude laterally from the semiconductor chip 2 in top view, may be partially or completely covered by the cover layer 3.

The first contact layer 51 is arranged along the vertical direction between the semiconductor chip 2 and the first inner connection layer 61. In particular, the first inner connection layer 61 has a larger cross-section than the first contact layer 51, and projects laterally beyond the first contact layer 51. The first contact layer 51 may have a larger cross-section than the semiconductor chip 2, and projects laterally beyond the semiconductor chip 2. The semiconductor chip 2 is disposed along the vertical direction between the first contact layer 51 and the second contact layer 52. Since the electrically insulating intermediate layer 3 is arranged between the first contact layer 51 and the second contact layer 52 and partially or, in particular, completely covers the lateral subregions 51L and 61L of the first contact layer 51 and the first inner connection layer 61, respectively, the short-circuit risks can be minimized.

As schematically shown in FIG. 1G, the second contact layer 52, which is in particular formed of a transparent and electrically conductive material, can completely cover the semiconductor chip 2 in top view. The semiconductor chip 2 has a lateral width 2B which is smaller than the lateral width 52B of the second contact layer 52. In top view, it can be clearly seen in FIG. 1G that the intermediate layer 3 outside the opening 40 has a smaller lateral width than the cover layer 4. Outside the opening 40, the second contact layer 52 may be formed exclusively on the intermediate layer 3. Outside the opening 40, the intermediate layer 3 or the second contact layer 52 may be completely covered by the cover layer 4. Inside the opening 40, the second contact layer 52 may be formed in top view in regions on the cover layer 3, the first contact layer 51, the first inner connection layer 61, and in regions on the semiconductor chip 2. Inside the opening 40, the cover layer 4 is not present. In other words, the intermediate layer 3 within the opening 40 is free from being covered by the cover layer 4.

The method steps described in FIGS. 1A to 1F are particularly suitable for the production of a component 10 according to all embodiments described herein. The features described in connection with the method steps can therefore also be used for the component 10 described herein, and vice versa.

The example embodiment of a component 10 shown in FIG. 2A substantially corresponds to the component 10 shown in FIG. 1F. In contrast thereto, the component 10 has an insulating layer 60. In particular, the insulating layer 60 is arranged exclusively within the cavity 40. The insulating layer 60 serves as a separating layer between the reflective layer 4R and the second contact layer 52, the first contact layer 51 and/or the first inner connection layer 61. In particular, the insulating layer 60 is directly adjacent to the reflective layer 4R, the first inner connection layer 61, the second contact layer 52 and/or the first contact layer 51. The insulating layer 60 may be contiguous or have at least two partial layers separated from each other.

As a further difference to FIG. 1F, the semiconductor chip 2 is only partially surrounded by the intermediate layer 3. However, the intermediate layer 3 may completely cover at least one side surface 2S of the semiconductor chip 2. In particular, the intermediate layer 3 partially covers further side surfaces 2S of the semiconductor chip 2. This is shown schematically in FIG. 2B, for example.

FIG. 2B shows a component 10 which is shown in particular in FIG. 2A in sectional view. In top view, the semiconductor chip 2, the first inner connection layer 61 and/or the first contact layer 51 may be fully enclosed by the insulating layer 60.

The example embodiment of a component 10 shown in FIG. 2B is substantially the same as the component 10 shown in FIG. 1G, except that the second contact layer 52 has a smaller lateral width 52B than the semiconductor chip 2. In top view, the second contact layer 52 only partially covers the semiconductor chip 2. It is also conceivable that the insulating layer 60 shown in FIG. 2B is not present. As a further alternative, it is possible that the insulating layer 60 is formed in such a way that it covers, in particular completely covers, the lateral subregions 51L and 61L of the first contact layer 51 and the first inner connection layer 61, respectively, for example if these lateral subregions 51L and 61L are not covered or are only partially covered by the intermediate layer 3. Such an embodiment of the insulating layer 60 can be applied to all embodiments of a component 10, in particular when the semiconductor chip 2 is not fully enclosed by the intermediate layer 3. In this case, the reflective layer 4R may be electrically conductive or electrically insulating.

The method step illustrated in FIG. 3A substantially corresponds to the method step illustrated in FIG. 1B of a method for producing a component 10. In contrast thereto, it is explicitly illustrated in FIG. 3A that the front side 2V of the semiconductor chip 2 is flush with the front side 3V of the intermediate layer 3. As a further difference to FIG. 1B, the intermediate layer 3 extends throughout the cavity 40. Within the opening 40, the second contact layer 52 may be formed exclusively as a planar contact.

A component 10, which is produced according to the method step illustrated in FIG. 3A, is schematically illustrated in particular in FIG. 3B in sectional view and in FIG. 3C in top view. The component 10 shown in FIGS. 3B and 3C is substantially the same as the component 10 shown in FIGS. 1F and 1G, except that the intermediate layer 3 may extend throughout the cavity 40 or throughout a plurality of cavities 40. If the component 10 has a plurality of cavities 40 and a plurality of semiconductor chips 2 arranged in the cavities 40, the intermediate layer 3 may be made contiguous as a whole. If the intermediate layer 3 extends into the respective cavities 40 but does not extend throughout the respective cavities 40, the intermediate layer 3 may have a plurality of laterally spaced sublayers, wherein the sublayers of the intermediate layer 3 each extend into one of the cavities 40.

As schematically shown in FIGS. 3B and 3C, the second contact layer 52 extends only into the cavity 40 and not throughout the cavity 40. Deviating therefrom, it is possible for all embodiments of the component 10 that the second contact layer 52 extends throughout the cavity 40 or throughout a plurality of cavities 40, in particular throughout all cavities 40. The second contact layer 52 may be contiguous. In this case, the semiconductor chips 2 arranged in the cavities 40 have a common electrode. The number of second inner connection layers 62, second through-contacts 72 and/or second outer connection layers 82 may be reduced. The individual control of the semiconductor chips 2 takes place in particular via the plurality of the first outer connection layers 81 and the first through-contacts 71.

The embodiment example of a component 10 shown in FIGS. 4A and 4B is substantially the same as the embodiment example of a component 10 shown in FIGS. 1F and 1G. In contrast, the semiconductor chip 2 is only partially enclosed by the intermediate layer 3. The intermediate layer 3 adjoins three different side surfaces 2S of the semiconductor chip 2. One side surface 2S of the semiconductor chip 2 may be completely covered by the material of the intermediate layer 3. Two other side surfaces 2S of the semiconductor chip 2 may be partially covered by the material of the intermediate layer 3.

As a further difference from FIGS. 1F and 1G, the second contact layer 52 is configured such that its lateral width 52B is smaller than the lateral width 2B of the semiconductor chip 2. In lateral directions, the intermediate layer 3 may be completely surrounded by the cover layer 4. If the intermediate layer 3 has a plurality of laterally spaced sub-layers each extending into one of the cavities 40, each of the sub-layers of the intermediate layer 3 may be completely surrounded by the cover layer 4 in lateral directions.

Furthermore, according to FIG. 4B, the lateral width 3B of the intermediate layer 3 is larger than the lateral width 2B of the semiconductor chip 2 or the lateral width 52B of the second contact layer 52. In contrast, it is possible that the lateral width 3B of the intermediate layer 3 is formed to be smaller than the lateral width 2B of the semiconductor chip 2. This is shown schematically in FIG. 5, for example.

The component 10 shown in FIG. 5 is thus essentially the same as the component 10 shown in FIG. 4B, with the difference that the intermediate layer 3 is only adjacent to one of the side surfaces 2S of the semiconductor chip 2 due to the reduced lateral width 3B. Thus, the intermediate layer 3 only partially covers the lateral subregions 51L and 61L of the first contact layer 51 and the first inner connection layer 61, respectively. The lateral subregions 51L and 61L of the first contact layer 51 or of the first inner connection layer 61, which are not or only partially covered by the intermediate layer 3 in top view, can be covered by the insulating layer 60 and/or by the encapsulation layer 9, in particular completely covered. A possible electrical short circuit between the second contact layer 52 or the reflective layer 4R and the first contact layer 51 or the first inner connection layer 61 can thus still be reliably prevented.

With the use of the intermediate layer 3, which is formed in particular prior to the formation of the cavity/s 40, many advantages can be achieved with respect to beam shaping, reduction of short circuit risks, as well as with respect to the producing of a component 10 described herein.

This application claims the priority of the German patent application DE 10 2021 110 089.5, the disclosure content of which is hereby included by reference.

The invention is not restricted to the exemplary embodiments by the description of the invention made with reference to the exemplary embodiments. The invention rather comprises any novel feature and any combination of features, including in particular any combination of features in the claims, even if this feature or this combination is not itself explicitly indicated in the patent claims or exemplary embodiments.

### LIST OF REFERENCE SIGNS

10 Component
10V Front side of the component
10R Rear side of the component
1 Carrier
1G Base body of the carrier
1V Front side of the carrier
1R Rear side of the carrier
2 Semiconductor chip
2B Lateral width of the semiconductor chip
2H Vertical height of the semiconductor chip
2S Side surface of the semiconductor chip
2V Front side of the semiconductor chip
3 Intermediate layer
30 Opening of the intermediate layer
3B Lateral width of the intermediate layer
3H Vertical height of the intermediate layer
3V Front side of the intermediate layer
4 Cover layer
4H Vertical height of the cover layer
4R Reflective layer
40 Cavity of the cover layer
40T vertical depth of the cavity
50 Intermediate connection layer
51 First contact layer
51L Lateral subregion of the first contact layer
52 Second contact layer
52B Lateral width of second contact layer
60 Insulating layer
61 First inner connection layer
61L Lateral subregion of the inner connection layer
62 Second inner connection layer
71 First through-contact
72 Second through-contact
80 Separating layer
81 First outer connection layer
82 Second outer connection layer
9 Encapsulation layer

1. A component comprising a carrier, at least one semiconductor chip, an intermediate layer and a cover layer, wherein
the semiconductor chip, the intermediate layer and the cover layer are arranged on the carrier,
the cover layer has at least one cavity wherein the semiconductor chip is arranged,
the intermediate layer is electrically insulating and is arranged in regions along the vertical direction between the carrier and the cover layer,
the intermediate layer extends along lateral direction into the cavity and adjoins the semiconductor chip, and
the cover layer has a vertical height that varies depending on the lateral positions of the cover layer and has a reduced vertical height at the positions of the intermediate layer.

2. The component according to claim 1,
wherein the intermediate layer completely surrounds the semiconductor chip in lateral directions.

3. The component according to claim 1,
wherein the intermediate layer has a lateral width larger than a lateral width of the semiconductor chip, the intermediate layer only partially surrounding the semiconductor chip in lateral directions.

4. The component according to claim 1,
wherein the intermediate layer has a lateral width smaller than a lateral width of the semiconductor chip, the intermediate layer only partially covering a side surface of the semiconductor chip.

5. The component according to claim 1,
wherein the semiconductor chip has a front side facing away from the carrier, and
wherein the front side is flush with the intermediate layer in the vertical direction or projects vertically beyond the intermediate layer.

6. The component according to any one of the preceding claims, claim 1, comprising a reflective layer formed on inner walls of the cavity, the reflective layer being formed from an electrically insulating material.

7. The component according to claim 1, comprising a reflective layer formed on inner walls of the cavity, the reflective layer being formed of an electrically conductive material.

8. The component according to claim 7, wherein the reflective layer is electrically isolated from the semiconductor chip.

9. The component according to claim 1, which comprises a first contact layer and a second contact layer for electrically contacting the semiconductor chip, wherein
the intermediate layer is arranged along the vertical direction in regions between the first contact layer and the second contact layer, and
the intermediate layer electrically insulates the first contact layer from the second contact layer.

10. The component according to claim 9, wherein
the semiconductor chip partially covers the first contact layer in top view,
the first contact layer has at least one subregion which, in top view, protrudes laterally from the semiconductor chip, and
the subregion is at least partially or completely covered by the intermediate layer in top view.

11. The component according to claim 9, wherein the semiconductor chip is arranged in the vertical direction between the first contact layer and the second contact layer, and wherein the second contact layer is arranged on a front side of the semiconductor chip facing away from the carrier and covers the front side at least partially or completely.

12. The component according to claim 1, wherein the carrier comprises a base body, through-contacts, inner connection layers and outer connection layers, wherein, wherein
the inner connection layers and the outer connection layers are arranged on opposite surfaces of the base body,
the through-contacts extend throughout the base body, and
the through-contacts each electrically connect one of the inner connection layers to one of the outer connection layers.

13. The component according to claim 2, wherein the intermediate layer is formed from a radiation-transmitting material.

14. The component according to any one of the preceding claims, claim 1, wherein
the semiconductor chip has a vertical height,
the cavity has a vertical depth, and
a ratio of vertical depth to vertical height from 2 to 20.

15. The component according to claim 1, comprising a plurality of semiconductor chips, wherein
the cover layer has a plurality of cavities, and
at least one or exactly one of the semiconductor chips is arranged in each of the cavities whose inner walls are provided with a reflective layer.

16. A method for producing a component comprising a carrier, at least one semiconductor chip, an intermediate layer and a cover layer, the method comprises the steps of:
placing the semiconductor chip on the carrier;
applying the intermediate layer to the carrier, the intermediate layer being laterally adjacent to the semiconductor chip; and
applying the cover layer to the intermediate layer and to the carrier, wherein
at least one cavity is formed in the cover layer, wherein the semiconductor chip is arranged in the at least one cavity,
the intermediate layer is formed to be electrically insulating and is arranged in regions along the vertical direction between the carrier and the cover layer,
the intermediate layer extends along lateral direction into the cavity, and
the cover layer has a vertical height that varies depending on the lateral positions of the cover layer and has a reduced vertical height at the positions of the intermediate layer.

17. The method according to claim 16,
wherein the semiconductor chip is electrically wired before the cover layer is applied to the intermediate layer and to the carrier.

18. The method according to claim 16,
wherein a planar contact layer is formed on a front side of the intermediate layer facing away from the carrier for electrically wiring the semiconductor chip.

19. A component comprising:
a carrier;
at least one semiconductor chip,
an intermediate layer; and
a cover layer,
wherein
the semiconductor chip, the intermediate layer and the cover layer are arranged on the carrier,
the cover layer has at least one cavity in which the semiconductor chip is arranged,
the intermediate layer is electrically insulating and is arranged in regions along the vertical direction between the carrier and the cover layer,
the intermediate layer extends along lateral direction into the cavity and adjoins the semiconductor chip,
the cover layer has a vertical height that varies depending on the lateral positions of the cover layer and has a reduced vertical height at the positions of the intermediate layer, and
the intermediate layer is formed from a radiation-transmitting material.
